(19) United States
(12) Patent Application Publication
(10) Pub. No.: US 2024/0379829 A1
(43) Pub. Date: Nov. 14, 2024

(54) SEMICONDUCTOR DEVICE AND MANUFACTURING METHOD THEREOF

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Ryo ONODERA, Tokyo (JP); Masahiro WATABE, Tokyo (JP)

(73) Assignee: Japan Display Inc., Tokyo (JP)

(21) Appl. No.: 18/656,855

(22) Filed: May 7, 2024

(30) Foreign Application Priority Data
May 12, 2023 (JP) 2023-079566

(51) Int. Cl. H01L 29/66; G02F 1/1368; H01L 29/45; H01L 29/786; H10K 59/122

(52) U.S. Cl. CPC H01L 29/66969; G02F 1/1368; H01L 29/45; H01L 29/7869; H10K 59/122

(57) ABSTRACT

A semiconductor device includes a gate electrode, a gate insulating layer over the gate electrode, an oxide semiconductor layer having a polycrystalline structure over the gate insulating layer, a source electrode and a drain electrode over the oxide semiconductor layer, and an interlayer insulating layer in contact with the oxide semiconductor layer, the interlayer insulating layer covering the source electrode and the drain electrode. The oxide semiconductor layer includes a first region overlapping one of the source electrode and the drain electrode and a second region in contact with the interlayer insulating layer. A difference between a thickness of the first region and a thickness of the second region is less than or equal to 1 nm.

### CROSS-REFERENCE TO RELATED APPLICATIONS

This application claims the benefit of priority to Japanese Patent Application No. 2023-079566, filed on May 12, 2023, the entire contents of which are incorporated herein by reference.

### FIELD

An embodiment of the present invention relates to a semiconductor device. Specifically, an embodiment of the present invention relates to a semiconductor device using an oxide semiconductor film as a channel. In addition, an embodiment of the present invention relates to a method for manufacturing a semiconductor device.

### BACKGROUND

In recent years, instead of a silicon semiconductor film using amorphous silicon, low-temperature polysilicon, and single-crystal silicon, a semiconductor device in which an oxide semiconductor film is used for a channel has been developed (for example, see Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The semiconductor device including an oxide semiconductor film has a simple structure and can be manufactured over a glass substrate by a low-temperature process, similar to a semiconductor device including an amorphous silicon film. Further, the semiconductor device including an oxide semiconductor film is known to have higher mobility than the semiconductor device including an amorphous silicon film.

### SUMMARY

A semiconductor device according to an embodiment of the present invention includes a gate electrode, a gate insulating layer over the gate electrode, an oxide semiconductor layer having a polycrystalline structure over the gate insulating layer, a source electrode and a drain electrode over the oxide semiconductor layer, and an interlayer insulating layer in contact with the oxide semiconductor layer, the interlayer insulating layer covering the source electrode and the drain electrode. The oxide semiconductor layer includes a first region overlapping one of the source electrode and the drain electrode and a second region in contact with the interlayer insulating layer. A difference between a thickness of the first region and a thickness of the second region is less than or equal to 1 nm.

A method for manufacturing a semiconductor device according to an embodiment of the present invention includes the steps of forming a gate electrode, forming a gate insulating layer over the gate electrode, forming an oxide semiconductor layer having a polycrystalline structure over the gate insulating layer, forming a source electrode and a drain electrode over the oxide semiconductor layer, and forming an interlayer insulating layer in contact with the oxide semiconductor layer. The interlayer insulating layer covers the source electrode and the drain electrode. The oxide semiconductor layer includes a first region overlapping one of the source electrode and the drain electrode and a second region in contact with the interlayer insulating layer. A difference between a thickness of the first region and a thickness of the second region is less than or equal to 1 nm.

### BRIEF DESCRIPTION OF DRAWINGS

FIG. 1 is a schematic cross-sectional view showing a configuration of a semiconductor device according to an embodiment of the present invention.

FIG. 2 is a schematic plan view showing a configuration of a semiconductor device according to an embodiment of the present invention.

FIG. 3 is a flowchart showing a method for manufacturing a semiconductor device according to an embodiment of the present invention.

FIG. 4 is a schematic cross-sectional view showing a method for manufacturing a semiconductor device according to an embodiment of the present invention.

FIG. 5 is a schematic cross-sectional view showing a method for manufacturing a semiconductor device according to an embodiment of the present invention.

FIG. 6 is a schematic cross-sectional view showing a method for manufacturing a semiconductor device according to an embodiment of the present invention.

FIG. 7 is a schematic cross-sectional view showing a method for manufacturing a semiconductor device according to an embodiment of the present invention.

FIG. 8 is a schematic cross-sectional view showing a method for manufacturing a semiconductor device according to an embodiment of the present invention.

FIG. 9 is a schematic cross-sectional view showing a method for manufacturing a semiconductor device according to an embodiment of the present invention.

FIG. 10 is a schematic cross-sectional view showing a method for manufacturing a semiconductor device according to an embodiment of the present invention.

FIG. 11 is a schematic cross-sectional view showing a method for manufacturing a semiconductor device according to an embodiment of the present invention.

FIG. 12 is a plan view showing an outline of a display device according to an embodiment of the present invention.

FIG. 13 is a block diagram showing a circuit configuration of a display device according to an embodiment of the present invention.

FIG. 14 is a circuit diagram showing a pixel circuit of a display device according to an embodiment of the present invention.

FIG. 15 is a schematic cross-sectional view showing a configuration of a display device according to an embodiment of the present invention.

FIG. 16 is a circuit diagram showing a pixel circuit of a display device according to an embodiment of the present invention.

FIG. 17 is a schematic plan view showing a configuration of a display device according to an embodiment of the present invention.

FIG. 18A is a graph showing electrical characteristics of a Sample A in an Example.

FIG. 18B is a graph showing electrical characteristics of a Sample B-1 in an Example.

FIG. 18C is a graph showing electrical characteristics of a Sample B-2 in an Example.

FIG. 18D is a graph showing electrical characteristics of a Sample C-1 in an Example.

FIG. 18E is a graph showing electrical characteristics of a Sample C-2 in an Example.

FIG. 19 is a graph showing threshold values calculated from electrical characteristics of each sample in the Examples.

FIG. 20 is a graph showing a field effect mobility (a field effect mobility in a saturated region) calculated from electrical characteristics of each sample in the Examples.

### DESCRIPTION OF EMBODIMENTS

In a conventional semiconductor device including an oxide semiconductor film, since the etching resistance of the oxide semiconductor film is low, it is difficult to control the shape of the oxide semiconductor film. In particular, in semiconductor devices manufactured using a large-area substrate such as a glass substrate, variations in the shape of oxide semiconductor films cause variations in the electrical characteristics of the semiconductor devices, which is a factor in reducing yield.

An embodiment of the present invention can provide a semiconductor device with stable electrical characteristics in which variations in a shape of an oxide semiconductor film are suppressed. Further, an embodiment of the present invention can provide a method for manufacturing a semiconductor device in which variations in a shape of an oxide semiconductor film are suppressed and yield is improved.

Hereinafter, embodiments of the present invention are described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of the respective portions in comparison with the actual embodiments. However, the illustrated shapes are merely examples, and do not limit the interpretation of the present invention. In the present specification and the drawings, the same reference signs are given to elements similar to those described previously with respect to the above-described drawings, and detailed description thereof may be omitted as appropriate.

In the present specification, a “semiconductor device” refers to any device that can function by utilizing semiconductor properties. A transistor and a semiconductor circuit are included in one form of a semiconductor device. For example, the semiconductor device in the following embodiments may be, an integrated circuit (IC) such as a display device or a micro-processing unit (MPU), or a transistor used in a memory circuit.

In the present specification, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, as long as there is no technical contradiction. Therefore, although a liquid crystal display device including a liquid crystal layer and an organic EL display device including an organic EL layer are exemplified as a display device in the following embodiments, the structure according to the present embodiment can be applied to a display device including the other electro-optic layers described above.

A direction from a substrate toward an oxide semiconductor layer is referred to as upper or above in each embodiment of the present invention. Conversely, a direction from the oxide semiconductor layer to the substrate is referred to as lower or below. For convenience of explanation, the phrase “above” or “below” is used for description, but for example, the substrate and the oxide semiconductor layer may be arranged so that the vertical relationship is reversed from that shown in the drawings. In the following explanation, for example, the expression “an oxide semiconductor layer on a substrate” merely describes the vertical relationship between the substrate and the oxide semiconductor layer as described above, and another member may be arranged between the substrate and the oxide semiconductor layer. The terms “above” or “below” mean a stacking order in which a plurality of layers is stacked, and may have a positional relationship in which a transistor and a pixel electrode do not overlap in a plan view when expressed as a pixel electrode above a transistor. On the other hand, the case of the expression “a pixel electrode vertically above a transistor” means a positional relationship in which the transistor and the pixel electrode overlap in a plan view. In addition, a plan view refers to viewing from a direction perpendicular to a surface of the substrate.

In the specification, the terms “film” and “layer” can be optionally interchanged with one another.

In the specification, the expression “α includes A, B, or C,” “α includes any of A, B, or C,” “α includes one selected from a group consisting of A, B and C,” and the like does not exclude the case where α includes a plurality of combinations of A to C unless otherwise specified. Further, these expressions do not exclude the case where α includes other elements.

In addition, the following embodiments can be combined as long as there is no technical contradiction.

### First Embodiment

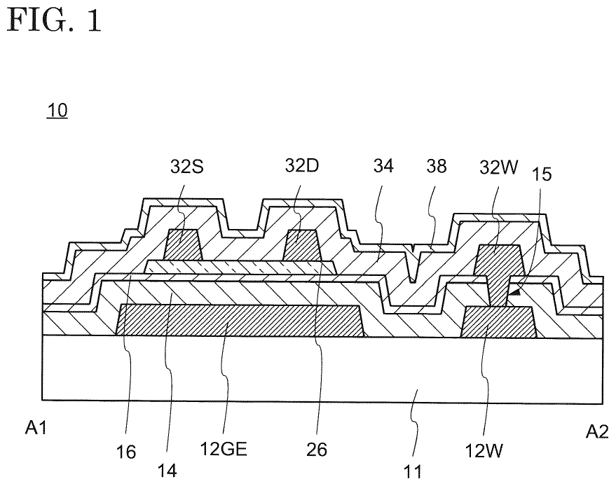

A semiconductor device 10 according to an embodiment of the present invention is described with reference to FIGS. 1 to 11.

### [Configuration of Semiconductor Device 10]

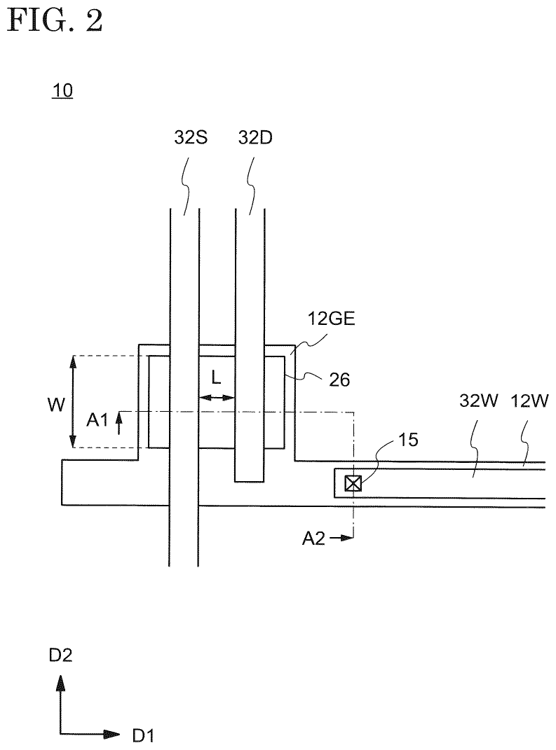

A configuration of the semiconductor device 10 according to an embodiment of the present invention is described with reference to FIGS. 1 and 2. FIG. 1 is a schematic cross-sectional view showing a configuration of the semiconductor device 10 according to an embodiment of the present invention. FIG. 2 is a schematic plan view showing a configuration of the semiconductor device 10 according to an embodiment of the present invention. The cross-sectional view shown in FIG. 1 corresponds to a cross section cut along a line A1-A2 shown in FIG. 2.

The semiconductor device 10 is arranged over a substrate 11 as shown in FIG. 1. The semiconductor device 10 includes a gate electrode 12GE, gate insulating layers 14 and 16, an oxide semiconductor layer 26, a source electrode 32S, a drain electrode 32D, and interlayer insulating layers 34 and 38. In the case where the source electrode 32S and the drain electrode 32D are not particularly distinguished from each other, they may be referred to as a source electrode and drain electrode 32. Further, the gate electrode 12GE, the gate insulating layers 14 and 16, and the oxide semiconductor layer 26 may be referred to as a transistor. The semiconductor device 10 is a so-called bottom-gate transistor in which the gate electrode 12GE is provided below the oxide semiconductor layer 26.

Although a bottom-gate transistor is exemplified as the semiconductor device 10 in the present embodiment, the semiconductor device 10 is not limited to the bottom-gate transistor. For example, the semiconductor device 10 may be a dual-gate transistor in which the gate electrode is provided over and below the oxide semiconductor layer 26.

The gate electrode 12GE is provided over the substrate 11. The gate insulating layers 14 and 16 are provided over the substrate 11 and the gate electrode 12GE. The gate insulating layers 14 and 16 have a stacked structure and the gate insulating layer 16 is provided over the gate insulating layer 14. The oxide semiconductor layer 26 is provided over the gate insulating layers 14 and 16. The source electrode 32S and the drain electrode 32D are provided over the oxide semiconductor layer 26. The interlayer insulating layers 34 and 38 are provided over the oxide semiconductor layer 26, the source electrode 32S, and the drain electrode 32D. The interlayer insulating layers 34 and 38 have a stacked structure and the interlayer insulating layer 38 is provided over the interlayer insulating layer 34. That is, the interlayer insulating layers 34 and 38 cover the source electrode 32S and the drain electrode 32D, and the interlayer insulating layer 34 is in contact with the oxide semiconductor layer 26.

In addition, although not shown in the figures, a metal oxide layer may be provided between the gate insulating layer 16 and the oxide semiconductor layer 26. The metal oxide layer may have the same pattern as the oxide semiconductor layer 26. For example, an oxide containing aluminum (e.g., aluminum oxide) may be used for the metal oxide layer. The thickness of the metal oxide layer is greater than or equal to 1 nm and less than or equal to 10 nm, preferably greater than or equal to 1 nm and less than 5 nm.

The oxide semiconductor layer 26 overlaps the gate electrode 12GE in a plan view as shown in FIG. 2. A direction D1 is a direction connecting the source electrode 32S and the drain electrode 32D, and a direction D2 is a direction perpendicular to the direction D1. A channel length L corresponds to a length of a region (channel region) of the oxide semiconductor layer 26 between the source electrode 32S and the drain electrode 32D in the direction D1, and a channel width W corresponds to a width of the channel region in the direction D2, in the semiconductor device 10. A region of the oxide semiconductor layer 26 overlapping the source electrode 32S is a source region, and a region of the oxide semiconductor layer 26 overlapping the drain electrode 32D is a drain region, in a plan view. That is, the channel region is located between the source region and the drain region.

A wiring 12W and a wiring 32W function as a gate wiring. The wiring 32W is electrically connected to the wiring 12W via a contact hole 15. Although details are described later, the wiring 12W is formed as the same layer as the gate electrode 12GE. In addition, the wiring 32W is formed as the same layer as the source electrode 32S and the drain electrode 32D. Further, the wiring 32W may not be provided over the wiring 12W.

The oxide semiconductor layer 26 has light transmittance and has a polycrystalline structure containing a plurality of grains. Although details are described later, the oxide semiconductor layer 26 having the polycrystalline structure can be formed by using a Poly-OS (Poly-crystalline Oxide Semiconductor) technique. Therefore, the oxide semiconductor included in the oxide semiconductor layer 26 may be described as Poly-OS hereinafter.

Poly-OS contains two or more metal elements including indium (that is, indium and at least one metal element other than indium), and the ratio of indium to the two or more metal elements is greater than or equal to 50%. Gallium (Ga), zinc (Zn), aluminum (Al), hafnium (Hf), yttrium (Y), zirconium (Zr), or a lanthanide-based element is used as the metal element other than indium. Elements other than those mentioned above may be used as the oxide semiconductor layer 26.

A particle diameter of the crystal grain contained in Poly-OS is greater than or equal to 0.1 μm, preferably greater than or equal to 0.3 μm, and more preferably greater than or equal to 0.5 μm. For example, the particle diameter of the crystal grain can be obtained using a SEM observation, a TEM observation, or an electron back scattered diffraction (EBSD) method of the oxide semiconductor layer 26.

Since the particle diameter of the crystal grain included in Poly-OS is greater than or equal to 0.1 μm as described above, there is a region containing only one crystal grain along a thickness direction, in the oxide semiconductor layer 26 having a thickness greater than or equal to 10 nm and less than or equal to 30 nm.

Poly-OS has excellent etching resistance. Although details are described later, Poly-OS has excellent etching resistance against an etching solution used in forming the source electrode 32S and the drain electrode 32D. Specifically, the oxide semiconductor layer 26 is hardly etched by the etching solution when forming the source electrode 32S and the drain electrode 32D. Therefore, a thickness of the first region of the oxide semiconductor layer 26 overlapping one of the source electrode 32S and the drain electrode 32D (that is, the source region or the drain region) is substantially the same as a thickness of the second region of the oxide semiconductor layer 26 not overlapping the source electrode 32S and the drain electrode 32D (that is, the channel region). In other words, the difference between the thickness of the first region and the thickness of the second region is less than or equal to 1 nm, preferably less than or equal to 0.5 nm, and more preferably less than or equal to 0.2 nm.

Variations in the shape of the oxide semiconductor layer can be a factor that destabilizes the electrical characteristics of the semiconductor device. In particular, variations in the thickness of the channel region of the oxide semiconductor layer are noticeable as variations in the electrical characteristics of the semiconductor device. For example, when the thickness of the channel region is smaller than a set value, the current flowing between the source electrode and the drain electrode decreases. Therefore, since an on-current of the semiconductor device decreases, a field effect mobility decreases. Further, when the oxide semiconductor layer is etched when forming the source and drain electrodes, not only the thickness of the channel region decreases, but also a recessed portion is formed on the top surface of the oxide semiconductor layer between the source electrode and the drain electrode. Although an interlayer insulating layer is deposited to cover the recessed portion formed on the top surface of the oxide semiconductor layer, a gap is formed between the oxide semiconductor layer and the interlayer insulating layer or between the source electrode and the drain electrode and the interlayer insulating layer when the interlayer insulating layer cannot sufficiently cover the recessed portion. In a semiconductor device in such a state, stable electrical characteristics cannot be obtained. That is, the yield of the semiconductor device decreases due to variations in the shape of the oxide semiconductor layer.

In contrast, the oxide semiconductor layer 26 includes Poly-OS and has high etching resistance in the semiconductor device 10. Therefore, since the thickness of the channel region is almost not reduced in forming the source electrode 32S and the drain electrode 32D, a recessed portion is not formed on the upper surface of the oxide semiconductor layer 26. Therefore, variations in the shape of the oxide semiconductor layer 26 are small in the semiconductor device 10, and stable electrical characteristics of the semiconductor device 10 can be obtained. For example, in the semiconductor device 10, even when the gate insulating layers 14 and 16 having a thickness of greater or equal to 400 nm are formed to improve breakdown voltage, the variation in field effect mobility is small and it is possible to obtain the field effect mobility (the field effect mobility in a linear region) greater than or equal to 15 cm²/Vs, further greater than or equal to 20 cm²/Vs.

### [Manufacturing Method of Semiconductor Device 10]

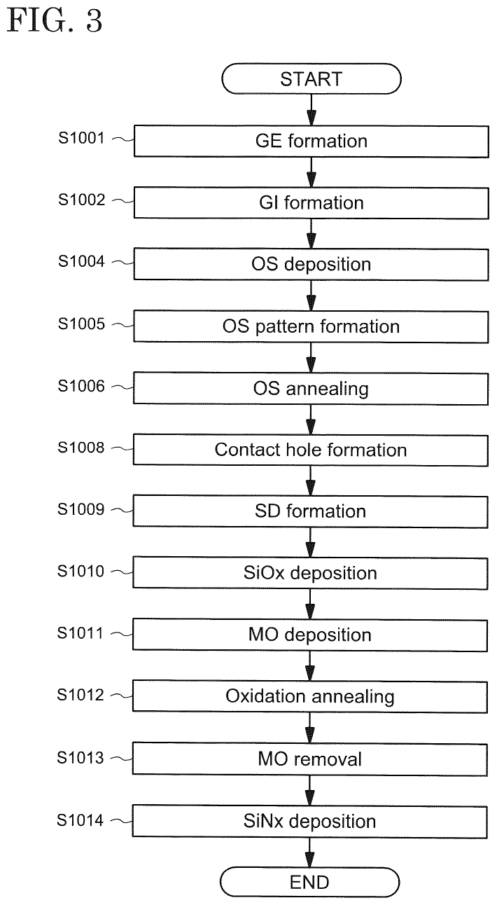

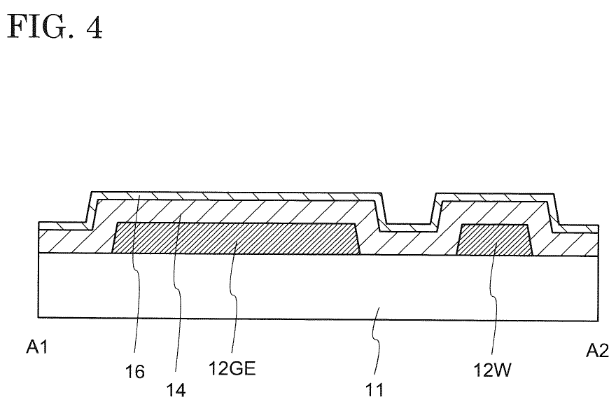

A method for manufacturing the semiconductor device 10 according to an embodiment of the present invention is described with reference to FIGS. 3 to 11. FIG. 3 is a flowchart illustrating a method for manufacturing the semiconductor device 10 according to an embodiment of the present invention. FIGS. 4 to 11 are schematic cross-sectional views showing a method for manufacturing the semiconductor device 10 according to an embodiment of the present invention. Hereinafter, each step of the flowchart shown in FIG. 3 is described in order.

In step S1001 (“GE formation”) of FIG. 3, the gate electrode 12GE is formed on the substrate 11 (see FIG. 4).

A rigid substrate having light transmittance, such as a glass substrate, a quartz substrate, a sapphire substrate, or the like, is used as the substrate 11. If the substrate 11 needs to have flexibility, a polyimide substrate, an acryl substrate, a siloxane substrate, a fluororesin substrate, or the like, or a substrate containing resin, is used as the substrate 11. In the case where the substrate containing resin is used as the substrate 11, an impurity element may be introduced into the resin to improve the heat resistance of the substrate 11. Further, in the case where the display device 10 is used for an integrated circuit, a substrate without translucency such as a semiconductor substrate such as a silicon substrate, a silicon carbide substrate, or a conductive substrate such as a stainless substrate may be used as the substrate 11.

The gate electrode 12GE is formed by processing a conductive film deposited by a sputtering method. For example, a metal material is used for the gate electrode 12GE. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys thereof or compounds thereof are used for the gate electrode 12GE. The above-described metal materials may be used in a single layer or in a stacked layer as the gate electrode 12GE.

In step S1002 (“GI formation”) of FIG. 3, the gate 20) insulating layers 14 and 16 are formed over the gate electrode 12GE (see FIG. 4). The gate insulating layers 14 and 16 are deposited by a CVD (Chemical Vapor Deposition) method or a sputtering method. An insulating material is used as the gate insulating layers 14 and 16. For example, an inorganic insulating material such as silicon oxide (SiOₓ), silicon oxynitride (SiOₓN_{y}), silicon nitride (SiNₓ), and silicon nitride oxide (SiNₓ O_{y}) are used as the insulating material of the gate insulating layers 14 and 16. The above SiOₓN_{y} is a silicon compound containing a smaller proportion (x>y) of nitrogen (N) than oxygen (O). SiNₓO_{y} is a silicon compound containing a smaller proportion of oxygen than nitrogen (x>y).

The gate insulating layer 14 in which an insulating material containing nitrogen is used and the gate insulating layer 16 in which an insulating material containing oxygen is used are preferably formed in this order above the substrate 11. When the insulating material containing nitrogen is used for the gate insulating layer 14, it can block impurities diffusing from the substrate 11 toward the oxide semiconductor layer 26. Further, when the insulating material containing oxygen is used for the gate insulating layer 16, it can release oxygen by a heat treatment. For example, the temperature of the heat treatment at which the insulating material containing oxygen releases oxygen is lower than or equal to 500° C., lower than or equal to 450° C., or lower than or equal to 400° C. In addition, the insulating material containing oxygen may release oxygen when heated in any of the steps of the manufacturing process of the semiconductor device 10.

A thickness of the gate insulating layer 14 is preferably greater than a thickness of the gate insulating layer 16. For example, the thickness of the gate insulating layer 14 is greater than or equal to 200 nm, 300 nm, or 400 nm. Further, for example, the thickness of the gate insulating layer 16 is greater than 50 nm, 100 nm, or 150 nm. Although the thickness of the gate insulating layers 14 and 16 (that is, the total thickness of the gate insulating layer 14 and the gate insulating layer 16) is preferably greater than or equal to 300 nm, the thickness of the gate insulating layers 14 and 16 is not limited thereto.

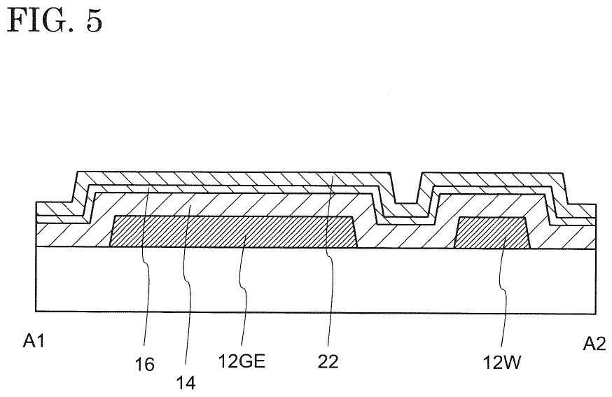

In step S1004 (“OS deposition”) of FIG. 3, an oxide semiconductor film 22 is deposited on the gate insulating layer 14 and 16 (see FIG. 5). The oxide semiconductor film 22 is formed by a sputtering method or an atomic layer deposition method (ALD). A thickness of the oxide semiconductor film 22 is greater than or equal to 10 nm and less than or equal to 50 nm, preferably greater than or equal to 10 nm and less than or equal to 40 nm, and more preferably greater than or equal to 10 nm and less than or equal to 30 nm.

A metal oxide having semiconductor properties can be used for the oxide semiconductor film 22. For example, an oxide semiconductor containing two or more metal elements including indium (In) (that is, indium and at least one metal element other than indium) is used for the oxide semiconductor film 22. In addition, the proportion of indium in the two or more metal elements is greater than or equal to 50%. Gallium (Ga), zinc (Zn), aluminum (Al), hafnium (Hf), yttrium (Y), zirconium (Zr), or a lanthanoid-based element is used as the metal element other than indium. The oxide semiconductor film 22 preferably contains a Group 13 element. In addition, a metal element other than the above may be used as the oxide semiconductor film 22.

In the case where the oxide semiconductor film 22 is crystallized by the OS annealing described later, the oxide semiconductor film 22 after the deposition and before the OS annealing preferably has an amorphous structure (for example, a structure in which the oxide semiconductor has few crystalline components is determined to be amorphous by an XRD method). That is, the oxide semiconductor film 22 is preferably deposited under a condition that the oxide semiconductor film 22 immediately after the deposition does not crystallize as much as possible. For example, in the case where the oxide semiconductor film 22 is deposited by a sputtering method, the oxide semiconductor film 22 is deposited while controlling the temperature of an object to be deposited (the substrate 11 and the structure deposited thereon).

Since ions generated in a plasma and atoms recoiled by a sputtering target collide with the object to be deposited when deposition is performed on the object to be deposited by the sputtering method, the temperature of the object to be deposited increases with the deposition treatment. When the temperature of the object to be deposited during the deposition treatment increases, microcrystals are contained in the oxide semiconductor film 22 immediately after the deposition. When the oxide semiconductor film 22 contains microcrystals, the particle diameter cannot be increased by subsequent OS annealing. For example, in order to control the temperature of the object to be deposited, the deposition can be performed while cooling the object to be deposited. For example, the object to be deposited can be cooled from the surface opposite to the depositing surface so that the temperature of the depositing surface of the object to be deposited (hereinafter, referred to as “deposition temperature”) is lower than or equal to 100° C., lower than or equal to 70° C., lower than or equal to 50° C., or lower than or equal to 30° C. In particular, the deposition temperature of the oxide semiconductor film 22 is preferably lower than or equal to 50° C. When the oxide semiconductor film 22 is deposited while the substrate 11 is cooled, the oxide semiconductor film 22 with few crystalline components can be obtained immediately after the deposition.

In the sputtering process, the oxide semiconductor film 22 having an amorphous structure is deposited under the condition of an oxygen partial pressure of less than or equal to 10%. When the oxygen partial pressure is high, the oxide semiconductor film 22 immediately after the deposition contains microcrystals due to excessive oxygen contained in the oxide semiconductor film 22. Therefore, the oxide semiconductor film 22 is preferably deposited under the condition that the oxygen partial pressure is low. For example, the oxygen partial pressure is greater than or equal to 1% and less than or equal to 5%, preferably greater than or equal to 2% and less than or equal to 4%. The distribution of oxygen in the deposition apparatus tends to be uneven under the condition that the oxygen partial pressure is less than 1%. As a result, the composition of oxygen in the oxide semiconductor film is also uneven, and the oxide semiconductor film containing a large amount of microcrystals is formed, or the oxide semiconductor film that does not crystallize even if the OS annealing treatment is performed later is deposited.

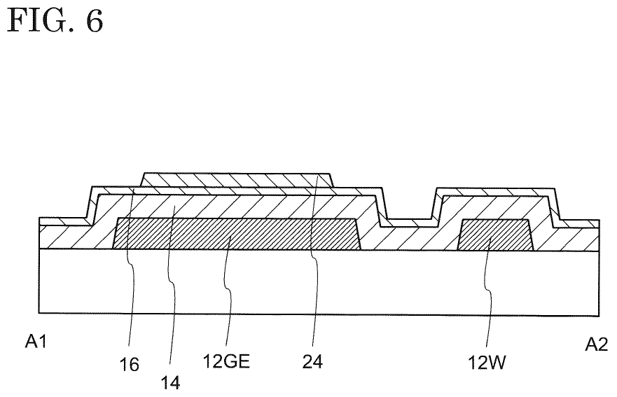

In step S1005 (“OS pattern formation”) of FIG. 3, a pattern of an oxide semiconductor layer 24 is formed (see FIG. 6). The pattern of the oxide semiconductor layer 24 is formed using photolithography. For example, a resist mask (not shown in the figures) is formed on the oxide semiconductor film 22, and the oxide semiconductor film 22 is etched using the resist mask. Wet etching may be used, or dry etching may be used as the etching method of the oxide semiconductor film 22. In the case of wet etching, an acidic etching solution can be used. For example, oxalic acid, PAN, sulfuric acid, hydrogen peroxide solution, or hydrofluoric acid can be used as the etching solution. The oxide semiconductor layer 24 having a predetermined pattern can be formed by etching. Thereafter, the resist mask is removed.

Forming the oxide semiconductor layer 24 having a predetermined pattern (that is, patterning of the oxide semiconductor film 22) is preferably performed before OS annealing. Poly-OS after OS annealing has a high etching resistance and is difficult to be patterned by etching. Further, damage (for example, oxygen defects in the oxide semiconductor layer 24) caused when forming the oxide semiconductor layer 24 can be repaired by performing OS annealing after the formation of the oxide semiconductor layer 24.

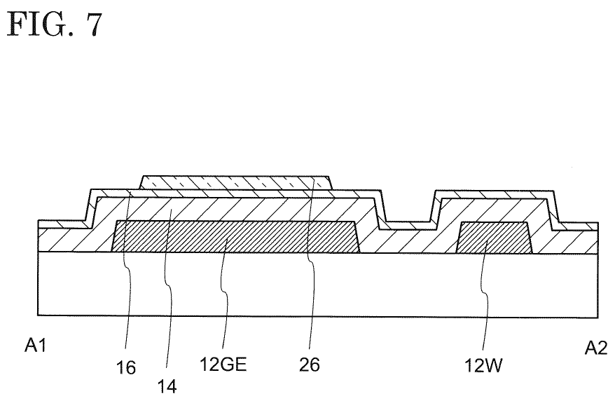

In step S1006 (“OS annealing”) of FIG. 3, the oxide semiconductor layer 26 is formed by performing a heat treatment (OS annealing) on the oxide semiconductor layer 24 after the oxide semiconductor layer 24 is formed (see FIG. 7). In OS annealing, the oxide semiconductor layer 24 is held at a predetermined reached temperature for a predetermined period. The predetermined reached temperature is higher than or equal to 300° C. and lower than or equal to 500° C., preferably higher than or equal to 350° C. and lower than or equal to 450° C. Further, the holding time at the reached temperature is greater than or equal to 15 minutes and less than or equal to 120 minutes, preferably greater than or equal to 30 minutes and less than or equal to 60 minutes. The oxide semiconductor layer 24 having an amorphous structure is crystallized by performing OS annealing, and the oxide semiconductor layer 26 having the polycrystalline structure is formed. That is, the oxide semiconductor layer 26 including Poly-OS is formed by OS annealing.

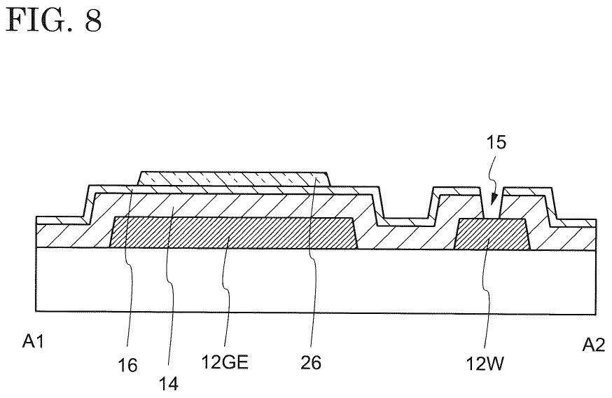

In step S1008 of FIG. 3 (“Contact hole formation”), the contact hole 15 is formed in the gate insulating layers 14 and 16 (see FIG. 8). This exposes an upper surface of the wiring 12W. In addition, in the case where the wiring 32W and the wiring 12W do not need to be connected, the step S1008 may not be performed.

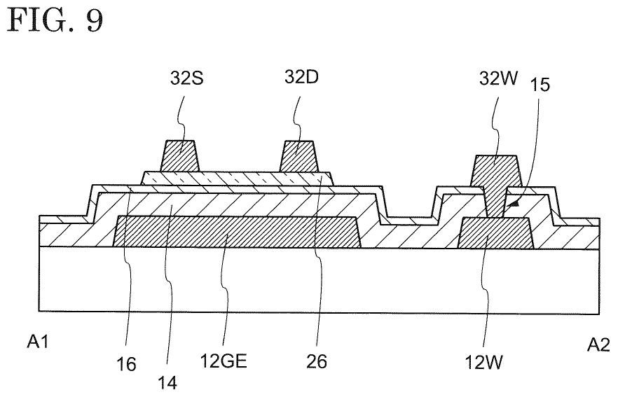

In step S1009 (“SD formation”) of FIG. 3, the source electrode 32S, the drain electrode 32D, and the wiring 32W are formed (see FIG. 9). The source electrode 32S, the drain electrode 32D, and the wiring 32W are formed by performing a patterning process of the conductive film deposited by a sputtering method using wet etching.

The same conductive material for the gate electrode 12GE is used for the source electrode 32S and the drain electrode 32D. That is, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys thereof or compounds thereof are used as a metal material of the conductive film for which the patterning process is performed. The above metal material may be used in a single layer or in a stacked layer for the conductive film. When the metal material is used in a single layer, the conductive film has a single-layer structure such as a MoW alloy, Ti, or Cu, for example. When the metal material is used in a stacked layer, the conductive film has a stacked structure of Ti, Al, and Ti (Ti/Al/Ti structure), Cu and Ti (Ti/Cu structure), or Ti, Cu, and Ti (Ti/Cu/Ti structure), for example. The source electrode 32S and the drain electrode 32D also have the same configuration as the conductive film. Further, the wiring 32W is formed simultaneously with the formation of the source electrode 32S and the drain electrode 32D. In addition, the conductive film preferably contains a low resistance metal material such as Al or Cu in order to reduce the resistance of the wiring 32W. Moreover, when the conductive film contains a metal material such as Cu, a barrier metal film containing Ti, Mo, or a MoW alloy is preferably provided between the oxide semiconductor layer 26 and the metal film containing Cu.

Here, the formation of the source electrode 32S and drain electrode 32D having a stacked structure is described using a Cu/Ti structure as an example. Ti is deposited on the oxide semiconductor layer 26 as a first metal film in contact with the oxide semiconductor layer 26, and then Cu is deposited on the first metal film as a second metal film. Subsequently, a predetermined resist pattern is formed on the second metal film, and wet etching is performed on the second metal film and the first metal film using the resist pattern as a mask. As a result, a second metal layer containing Ti and a first metal layer containing Cu are formed from the second metal film and the first metal film, respectively.

In forming the source electrode 32S and the drain electrode 32D, a hydrogen peroxide-based etching solution is used as an etching solution for wet etching. The hydrogen peroxide-based etching solution includes a chelating agent such as ethylenediaminetetraacetic acid (EDTA) or phosphoric acid.

Poly-OS has an excellent etching resistance. Specifically, the etching rate of the etching solution used in forming the source electrode 32S and the drain electrode 32D is very low. This means that Poly-OS is hardly etched by the etching solution. In other words, in the semiconductor device 10, even when the conductive film is deposited directly on the oxide semiconductor layer 26 and the conductive film is patterned to form the source electrode 32S and the drain electrode 32D, the channel of the oxide semiconductor layer 26 is hardly etched. Therefore, the thickness of the first region of the oxide semiconductor layer 26 that overlaps one of the source electrode 32S and the drain electrode 32D (that is, the source region or the drain region) is substantially the same as the thickness of the second region of the oxide semiconductor layer 26 that does not overlap one of the source electrode 32S and the drain electrode 32D (that is, the channel region). In other words, the thickness of the oxide semiconductor layer can be controlled such that the difference between the thickness of the first region and the thickness of the second region is less than or equal to 1.0 nm, preferably less than or equal to 0.5 nm, more preferably less than or equal to 0.2 nm.

For example, the etching rate of the oxide semiconductor layer 26 with respect to the etching solution (solution temperature: 30° C.) used in forming the source electrode 32S and the drain electrode 32D is less than 0.01 nm/sec, or less than 0.20 nm/min. That is, even when the etching time is 60 seconds, the decrease in the thickness of the oxide semiconductor layer 26 is less than 0.20 nm.

In a semiconductor device including an oxide semiconductor layer such as IGZO that does not have a polycrystalline structure, when a source electrode and a drain electrode are formed by patterning a conductive film deposited directly on the oxide semiconductor layer, the oxide semiconductor layer is also etched by wet etching in the patterning of the conductive film. Therefore, in the case of manufacturing the semiconductor device in which the thickness of the channel region of the oxide semiconductor layer is less than or equal to 40 nm, an oxide semiconductor film with a thickness of about 90 nm is deposited and the etching time needs to be adjusted so that the thickness of the channel region is less than or equal to 40 nm when forming the source electrode and the drain electrode. However, when the etching rate is high, it is difficult to precisely control the thickness of the channel region by the etching time. In this case, the variation in the thickness of the channel region increases.

Further, a recessed portion is formed on the upper surface of the oxide semiconductor layer when the thickness of the channel region is greatly reduced. Although the interlayer insulating layer is deposited so as to cover the recessed portion formed on the upper surface of the oxide semiconductor layer, the interlayer insulating layer cannot sufficiently cover the recessed portion when a depth of the concave portion is large. That is, a gap may be formed between the oxide semiconductor layer and the interlayer insulating layer or between the source electrode and drain electrode and the interlayer insulating layer. This can be a factor that causes not only destabilization of the electrical characteristics of the semiconductor device but also a reduction of the reliability of the semiconductor device.

In contrast, the oxide semiconductor layer 26 includes Poly-OS and has a high etching resistance. Therefore, the thickness of the channel region of the oxide semiconductor layer 26 can be controlled only by depositing the oxide semiconductor film 22 without considering the reduction in the thickness of the oxide semiconductor film 22 due to the etching solution used in forming the source electrode 32S and the drain electrode 32D. Therefore, the oxide semiconductor film 22 can be deposited with a thickness greater than or equal to 10 nm and less than or equal to 50 nm, preferably greater than or equal to 10 nm and less than or equal to 40 nm, and more preferably greater than or equal to 10 nm and less than or equal to 30 nm. Further, since the oxide semiconductor layer 26 has a high etching resistance, the selectivity of metal materials that can be used for the source electrode 32S, drain electrode 32D, and wiring 32W is improved.

Since the oxide semiconductor layer 26 has an excellent etching resistance, it is possible to increase the etching rate of the conductive film in forming the source electrode 32S and the drain electrode 32D. For example, the etching rate of the first metal film in contact with the oxide semiconductor layer 26 is greater than or equal to 0.1 nm/sec, preferably greater than or equal to 0.5 nm/sec, and more preferably greater than or equal to 0.9 nm/sec. Further, when the second metal film deposited on the first metal film contains Cu, the etching rate of the second metal film is greater than or equal to 1.0 nm/sec, preferably greater than or equal to 2.0 nm/sec, and more preferably greater than or equal to 3.0 nm/sec.

In addition, although the oxide semiconductor layer 26 is hardly etched in forming the source electrode 32S and drain electrode 32D, the gate insulating layer 16 may be etched depending on the type of etching solution. For example, over-etching is performed instead of just-etching in order to prevent unnecessary conductive films from remaining. In this case, the gate insulating layer 16 exposed from the conductive film is etched. In the gate insulating layer 16, the difference between the thickness of a region that overlaps the oxide semiconductor layer 26 and the thickness of a region that does not overlap the oxide semiconductor layer 26 is greater than or equal to 5 nm, greater than or equal to 10 nm, or greater than or equal to 15 nm. Further, since the time of over-etching is controlled so that the thickness of the gate insulating layer 16 does not become too small, the difference between the thickness of the region that overlaps the oxide semiconductor layer 26 and the thickness of the region that does not overlap the oxide semiconductor layer 26 is less than or equal to 50 nm, preferably less than or equal to 30 nm, and more preferably less than or equal to 20 nm in the gate insulating layer 16.

The interlayer insulating layer 34 is deposited on the oxide semiconductor layer 26, the source electrode 32S, and the drain electrode 32D, in step S1010 (“SiOₓ deposition”) of FIG. 3. An insulating material containing oxygen is preferably used as the interlayer insulating layer 34. For example, silicon oxide (SiOₓ) or silicon oxynitride (SiOₓN_{y}) is used as the interlayer insulating layer 34. Further, an insulating film with few defects is preferably used as the interlayer insulating layer 34. For example, in the case where the composition ratio of oxygen in the interlayer insulating layer 34 is compared with the composition ratio of oxygen in an insulating film (hereinafter, referred to as “the other insulating film”) having the same composition as the interlayer insulating layer 34, the composition ratio of oxygen in the interlayer insulating layer 34 is closer to the stoichiometric ratio with respect to the insulating film than the composition ratio of oxygen in the other insulating film. For example, when silicon oxide (SiOₓ) is used for each of the interlayer insulating layer 34 and the gate insulating layer 14, the interlayer insulating layer 34 has a composition ratio closer to the stoichiometric ratio of silicon oxide (SiO₂) than the gate insulating layer 14. A layer in which no defects are observed when evaluated by an electron-spin resonance method (ESR) may be used as the interlayer insulating layer 34.

The interlayer insulating layer 34 can be deposited using the same deposition method as the gate insulating layers 14 and 16. In order to increase the composition ratio of oxygen in the interlayer insulating layer 34, the film may be formed at a relatively low temperature (for example, a deposition temperature of less than 350° C.). Further, the interlayer insulating layer 34 may be deposited at a deposition temperature of higher than or equal to 350° C. in order to form an insulating film with few defects as the interlayer insulating layer 34. Furthermore, an oxygen-implantation treatment may be performed on part of the interlayer insulating layer 34 after the interlayer insulating layer 34 is deposited.

A thickness of the interlayer insulating layer 34 is greater than or equal to 50 nm and less than or equal to 300 nm, greater than or equal to 60 nm and less than or equal to 200 nm, or greater than or equal to 70 nm and less than or equal to 150 nm.

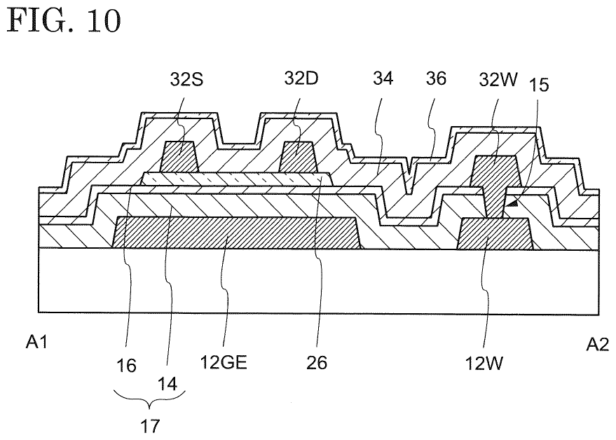

In step S1011 (“MO deposition”) of FIG. 3, a metal oxide film 36 is deposited on the interlayer insulating layer 34 (see FIG. 10). The metal oxide film 36 is deposited by a sputtering method or an atomic layer deposition method (ALD).

A metal oxide film containing aluminum as a main component is used as the metal oxide film 36. For example, an inorganic insulating film such as aluminum oxide (AlOₓ), aluminum oxynitride (AlOₓ N_{y}), aluminum nitride oxide (AlNₓO_{y}), or aluminum nitride (AlNₓ) is used as the metal oxide film 36. The metal oxide film containing aluminum as a main component means that the ratio of aluminum contained in the metal oxide film is greater than or equal to 1% of the total amount of the metal oxide film. The ratio of aluminum contained in the metal oxide film 36 may be greater than or equal to 5% and less than or equal to 70%, greater than or equal to 10% and less than or equal to 60%, or greater than or equal to 30% and less than or equal to 50% of the total amount of the metal oxide film 36. The ratio may be a mass ratio or a weight ratio.

A thickness of the metal oxide film 36 is greater than or equal to 1 nm and less than or equal to 50 nm, preferably greater than or equal to 1 nm and less than or equal to 30 nm. Aluminum oxide is preferably used as the metal oxide film 36. Aluminum oxide has a high barrier property against gas such as oxygen or hydrogen. In this case, the barrier property refers to a function of suppressing a gas such as oxygen or hydrogen from passing through the aluminum oxide. That is, it means that the gas such as oxygen or hydrogen in the layer provided below the aluminum oxide film is not moved to the layer provided over the aluminum oxide film. Alternatively, it means that the gas such as oxygen or hydrogen in the layer provided over the aluminum oxide film is not moved to the layer arranged below the aluminum oxide film.

In step S1012 (“Oxidation annealing”) of FIG. 3, a heat treatment is performed while the interlayer insulating layer 34 and the metal oxide film 36 are deposited over the oxide semiconductor layer 26 (see FIG. 10). In this case, for example, the oxidation annealing may be performed at higher than or equal to 300° C. and lower than or equal to 450° C. As a result, the oxygen emitted from the interlayer insulating layer 34 is supplied to the oxide semiconductor layer 26. Arranging the metal oxide film 36 so as to cover the substrate 11 makes it possible to suppress the oxygen released from the interlayer insulating layer 34 from being released to the outside of the metal oxide film 36.

Many oxygen defects occur in the oxide semiconductor layer 26 during the process from the deposition of the oxide semiconductor layer 26 to the deposition of the interlayer insulating layer 34 on the oxide semiconductor layer 26. However, the oxygen released from the interlayer insulating layer 34 is supplied to the oxide semiconductor layer 26 by the oxidation annealing of step S1012, and the oxygen defects are repaired.

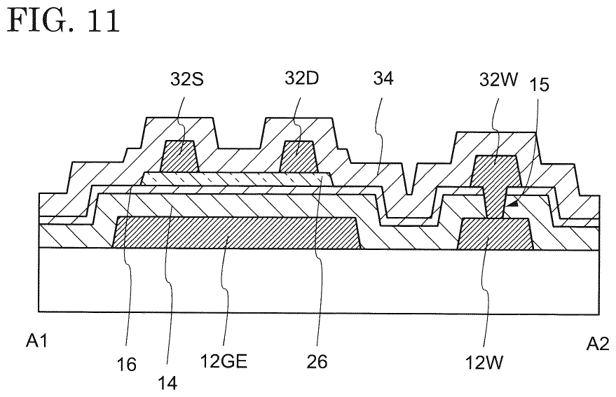

In step S1013 (“MO removal”) of FIG. 3, the metal oxide film 36 is removed (see FIG. 11). For example, the metal oxide film 36 may be removed using dilute hydrofluoric acid (DHF).

In step S1014 (“SiNₓ deposition”) of FIG. 3, the interlayer insulating layer 38 is deposited on the interlayer insulating layer 34. An insulating material containing nitrogen is preferably used for the interlayer insulating layer 38. For example, silicon nitride (SiNₓ) or silicon nitride oxide (SiNₓO_{y}) is used for the interlayer insulating layer 38. The interlayer insulating layer 38 can be deposited using the same deposition method as the gate insulating layers 14 and 16.

The semiconductor device 10 shown in FIG. 1 can be manufactured through the above steps.

As described above, in the manufacturing process of the semiconductor device 10, the variation in the shape of the oxide semiconductor layer 26 is suppressed by forming the oxide semiconductor layer 26 including Poly-OS having a high etching resistance. In particular, the variation in the thickness of the channel region of the oxide semiconductor layer 26 can be reduced. As a result, the semiconductor device 10 has stable electrical characteristics and the yield of the semiconductor device 10 is improved.

### Second Embodiment

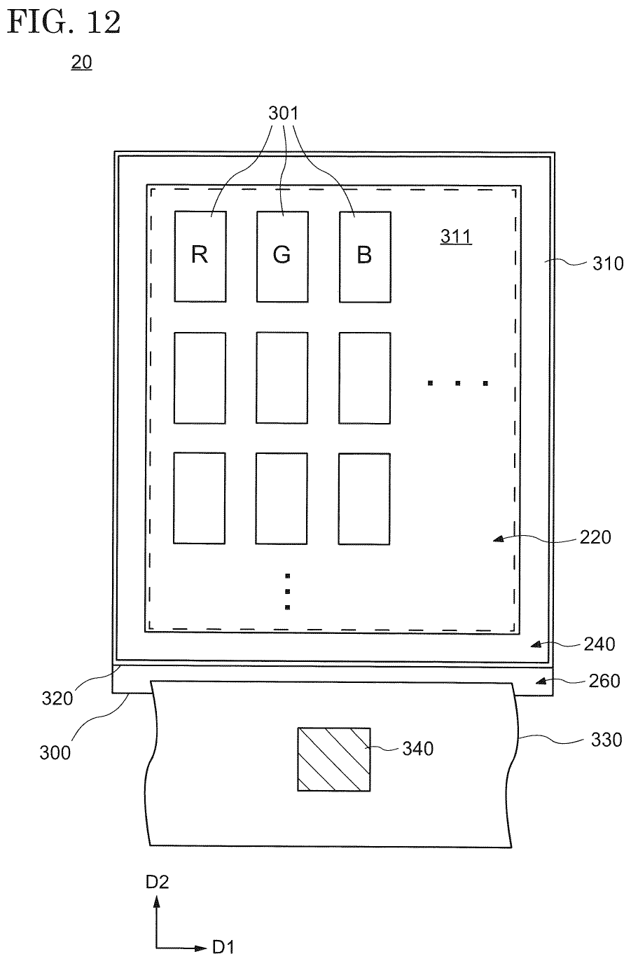

A display device 20 using the semiconductor device 10 according to an embodiment of the present invention is described with reference to FIGS. 12 to 15. A configuration in which the semiconductor device 10 described in the First Embodiment is applied to a circuit of a liquid crystal display device is described in the embodiment described below.

### [Outline of Display Device 20]

FIG. 12 is a schematic plan view showing an outline of the display device 20 according to an embodiment of the present invention. The display device 20 includes an array substrate 300, a sealing portion 310, a counter substrate 320, a flexible printed circuit board 330 (FPC 330), and an IC chip 340, as shown in FIG. 12. The array substrate 300 and the counter substrate 320 are bonded together by the sealing portion 310. A plurality of pixel circuits 301 is arranged in a matrix in a liquid crystal region 220 surrounded by the sealing portion 310. The liquid crystal region 220 is a region that overlaps a liquid crystal element 311 described later in a plan view.

A sealing region 240 where the sealing portion 310 is provided is a region around the liquid crystal region 220. The FPC 330 is provided in a terminal region 260. The terminal region 260 is a region where the array substrate 300 is exposed from the counter substrate 320 and is provided outside the sealing region 240. The outside of the sealing region 240 means the region surrounded by the region where the sealing portion 310 is provided and the outside of the sealing portion 310. The IC chip 340 is provided on the FPC 330. The IC chip 340 supplies a signal for driving each pixel circuit 301.

### [Circuit Configuration of Display Device 20]

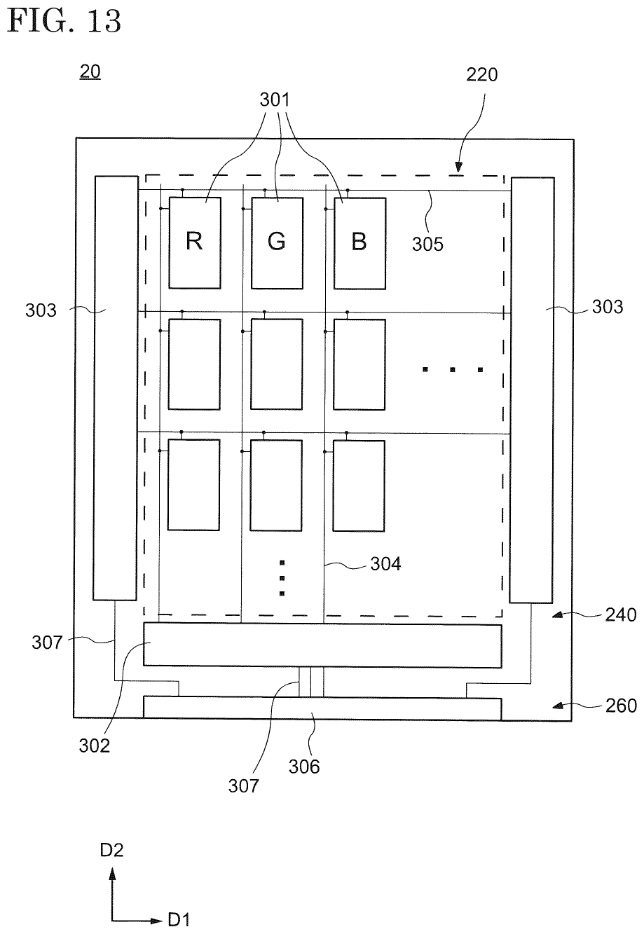

FIG. 13 is a block diagram showing a circuit configuration of the display device 20 according to an embodiment of the present invention. A source driver circuit 302 is provided at a position adjacent to the liquid crystal region 220 in which the pixel circuit 301 is arranged in the second direction D2 (column direction), and a gate driver circuit 303 is provided at a position adjacent to the liquid crystal region 220 in the first direction D1 (row direction), as shown in FIG. 13. The source driver circuit 302 and the gate driver circuit 303 are provided in the sealing region 240. However, the region where the source driver circuit 302 and the gate driver circuit 303 are provided is not limited to the sealing region 240, and any region may be used as long as it is outside the region where the pixel circuit 301 is provided.

A source wiring 304 extends from the source driver circuit 302 in the second direction D2 and is connected to the plurality of pixel circuits 301 arranged in the second direction D2. The gate electrode 12GE extends from the gate driver circuit 303 in the first direction D1 and is connected to the plurality of pixel circuits 301 arranged in the first direction D1.

A terminal portion 306 is provided in the terminal region 260. The terminal portion 306 and the source driver circuit 302 are connected by a connecting wiring 307. Similarly, the terminal portion 306 and the gate driver circuit 303 are connected by the connecting wiring 307. The FPC 330 is connected to the terminal portion 306 which allows an external device to which the FPC 330 is connected to be connected to the display device 20, and each pixel circuit 301 provided in the display device 20 is driven by a signal from the external device.

The semiconductor device 10 according to the first embodiment is used as a transistor included in the pixel circuit 301, the source driver circuit 302, and the gate driver circuit 303.

### [Pixel Circuit 301 of Display Device 20]

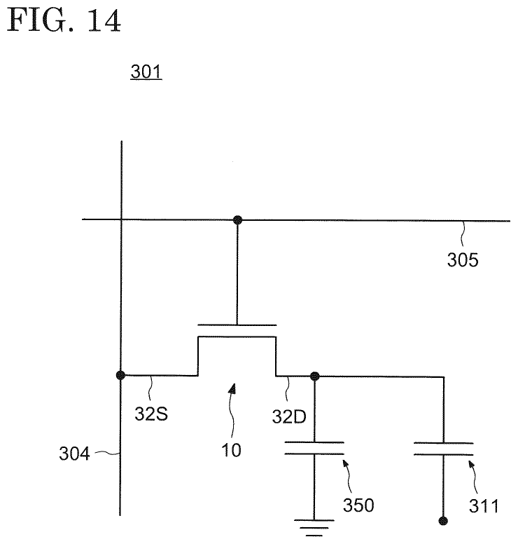

FIG. 14 is a circuit diagram showing the pixel circuit 301 of the display device 20 according to an embodiment of the present invention. The pixel circuit 301 includes elements such as the semiconductor device 10, a storage capacitor 350, and the liquid crystal element 311, as shown in FIG. 14. The semiconductor device 10 includes the gate electrode 12GE, the oxide semiconductor layer 26, the source electrode 32S, and the drain electrode 32D. The gate electrode 12GE is connected to a gate wiring 305. The source electrode 32S is connected to the source wiring 304. The drain electrode 32D is connected to the storage capacitor 350 and the liquid crystal element 311.

### [Configuration of Display Device 20]

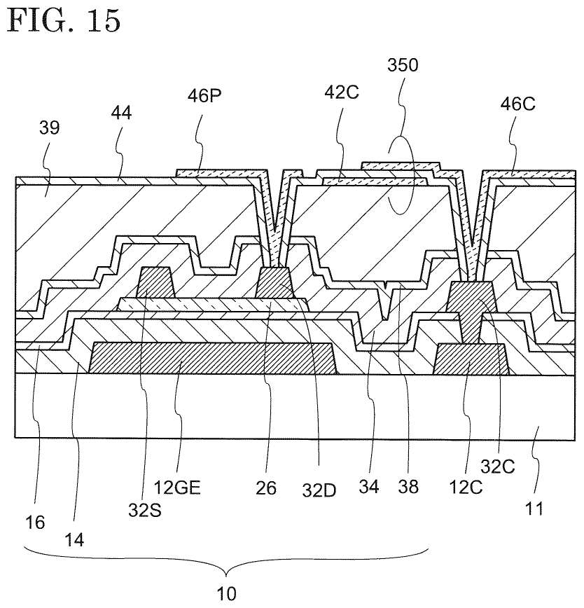

FIG. 15 is a schematic cross-sectional view of the display device 20 according to an embodiment of the present invention. The semiconductor device 10 is applied to the display device 20 shown in FIG. 15.

The gate electrode 12GE is provided on the substrate 11 as shown in FIG. 15. The gate insulating layers 14 and 16 are provided over the gate electrode layer 12GE. The oxide semiconductor layer 26 is provided over the gate insulating layers 14 and 16. The source electrode 32S and the drain electrode 32D are provided on the oxide semiconductor layer 26.

The interlayer insulating layers 34 and 38 are arranged over the source electrode 32S and the drain electrode 32D. An insulating layer 39 is provided over the interlayer insulating layers 34 and 38. The insulating layer 39 is provided in order to reduce unevenness caused by the semiconductor device 10. A contact hole is formed in the interlayer insulating layers 34 and 38 and the insulating layer 39 so as to expose the upper surface of the source electrode 32S. A common electrode 42C provided in common to a plurality of pixels is provided on the insulating layer 39. An insulating layer 44 is provided on the common electrode 42C. The insulating layer 44 is provided inside the contact hole. Forming the insulating layer 44 with a silicon nitride film makes it possible to suppress moisture from entering from the contact hole via the insulating layer 44. A pixel electrode 46P is provided on the insulating layer 44 and inside the contact hole. The pixel electrode 46P is connected to the drain electrode 32D.

Further, a wiring 12C is provided over the substrate 11 and is connected to a wiring 32C via the contact hole provided in the gate insulating layers 14 and 16. The wiring 12C and the wiring 32C function as a capacitance wiring. Furthermore, an electrode 46C is provided over an inside an opening of the insulating layer 39. The storage capacitor 350 is formed by the common electrode 42C, the insulating layer 44, and the electrode 46C.

Although a configuration in which the semiconductor device 10 is used for the pixel circuit 301 is exemplified in the present embodiment, the semiconductor device 10 may be used for a peripheral circuit including the source driver circuit 302 and the gate driver circuit 303.

### Third Embodiment

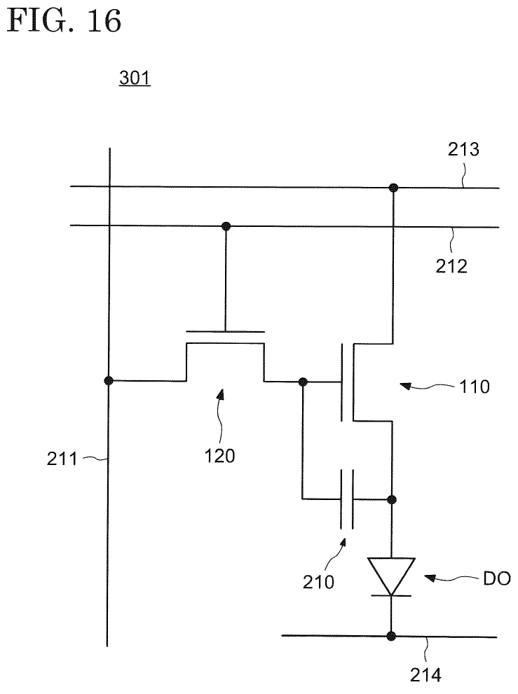

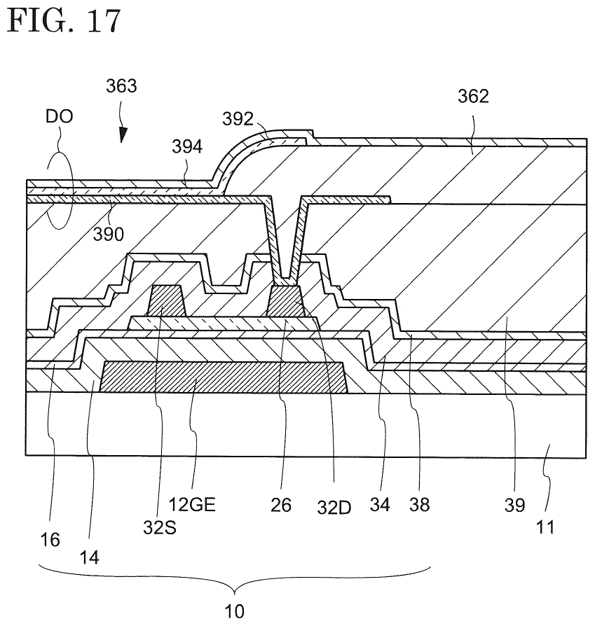

The display device 20 using the semiconductor device 10 according to an embodiment of the present invention is described with reference to FIGS. 16 and 17. A configuration in which the semiconductor device 10 described in the First Embodiment is applied to a circuit of an organic EL display device is described in the present embodiment. Since the outline and circuit configuration of the display device 20 are the same as those shown in FIGS. 12 and 13, details are omitted.

### [Pixel Circuit 301 of Display Device 20]

FIG. 16 is a circuit diagram showing a pixel circuit of the display device 20 according to an embodiment of the present invention. The pixel circuit 301 includes elements such as a driving transistor 110, a select transistor 120, a storage capacitor 210, and a light-emitting element DO, as shown in FIG. 16. The driving transistor 110 and the select transistor 120 have the same configuration as that of the semiconductor device 10. A source electrode of the select transistor 120 is connected to a signal line 211, and a gate electrode of the select transistor 120 is connected to a gate line 212. A source electrode of the driving transistor 110 is connected to an anode power line 213, and a drain electrode of the driving transistor 110 is connected to one end of the light-emitting element DO. The other end of the light-emitting element DO is connected to a cathode power line 214. A gate electrode of the driving transistor 110 is connected to a drain electrode of the select transistor 120. The storage capacitor 210 is connected to the gate electrode and drain electrode of the driving transistor 110. A gradation signal that determines an emission intensity of the light-emitting element DO is supplied to the signal line 211. A signal for selecting a pixel row to which the gradation signal is written is supplied to the gate line 212.

### [Cross-Sectional Structure of Display Device 20]

FIG. 17 is a schematic cross-sectional view showing a configuration of the display device 20 according to an embodiment of the present invention. Although the configuration of the display device 20 shown in FIG. 17 is similar to that of the display device 20 shown in FIG. 15, the structure above the insulating layer 39 of the display device 20 shown in FIG. 17 is different from the structure above the insulating layer 39 of the display device 20 shown in FIG. 15. Hereinafter, among the descriptions of the configuration of the display device 20 shown in FIG. 17, descriptions of the same configurations as those of the display device 20 shown in FIG. 15 are omitted, and differences between the two are described.

The display device 20 includes a pixel electrode 390, a light-emitting layer 392, and a common electrode 394 (the light emitting element DO) above the insulating layer 39, as shown in FIG. 17. The pixel electrode 390 is provided on the insulating layer 39 and inside the contact hole formed in the interlayer insulating layers 34 and 38 and the insulating layer 39. An insulating layer 362 is provided on the pixel electrode 390. An opening 363 is provided in the insulating layer 362. The opening 363 corresponds to the light emitting region. That is, the insulating layer 362 defines a pixel. The light emitting layer 392 and the common electrode 394 are provided over the pixel electrode 390 exposed by the opening 363. The pixel electrode 390 and the light emitting layer 392 are provided separately for each pixel. On the other hand, the common electrode 394 is arranged in common to a plurality of pixels. Different materials are used for the light emitting layer 392 depending on the display color of the pixel.

Although the configuration in which the semiconductor device 10 described in the First Embodiment is applied to the liquid crystal display device and the organic EL display device has been exemplified in the Second Embodiment and Third Embodiment, the semiconductor device 10 may be applied to a display device (for example, a self-luminous display device or an electronic paper type display device other than the organic EL display device) other than these display devices. In addition, the semiconductor device 10 can be applied from a medium-sized display device to a large-sized display device without any particular limitation. Even when manufacturing using the large-area substrate, variations in the shape of the oxide semiconductor layer 26 in the semiconductor device 10 are small. Therefore, in the case where the semiconductor device 10 is applied to the display device 20, uneven display can be reduced. In addition, the yield in manufacturing the display device 20 can be improved.

### Examples

The semiconductor device 10 according to an embodiment of the present invention is described in detail based on an example. However, the semiconductor device 10 is not limited to the example described below.

### [Etching Rate]

The etching rate of each Poly-OS included in the oxide semiconductor layer, MoW, Ti, Al, and Cu used for the source electrode and drain electrode, and silicon oxide (SiOₓ) and silicon nitride (SiNₓ) for the gate insulating layer was calculated using the etching solution used in forming the source electrode and the drain electrode.

Samples in which the etching rates were measured are described. Each sample was obtained by depositing a single film of each material on a silicon wafer. In addition, in the Poly-OS sample, an oxide semiconductor layer having a polycrystalline structure was formed by performing an OS annealing treatment after depositing an oxide semiconductor film having an amorphous structure.

Wet etching (room temperature) of each material was performed using GHP-3 (manufactured by Kanto Kagaku Co., Ltd.) containing a chelating agent and BTF-3 (manufactured by Kanto Kagaku Co., Ltd.) containing phosphoric acid as etching solutions. After wet etching, the thickness of each material was measured. For each material, wet etching was performed under conditions with different etching times, and multiple thickness data with different etching times were obtained. A calibration curve was created based on the etching time and the thickness data, and the etching rate of each material was calculated. Table 1 shows the calculated etching rate of each material. In addition, “less than 0.01 nm/sec” in Table 1 means that the thicknesses before and after wet etching are approximately the same, and the film is hardly etched by wet etching.

TABLE 1

| | GHP-3 | BTF-3 |
|---|---|---|
| Poly-OS | less than 0.01 nm/sec | less than 0.01 nm/sec |
| MoW | 0.14 nm/sec | 0.09 nm/sec |
| Ti | less than 0.01 nm/sec | 0.93 nm/sec |
| Al | 0.01 nm/sec | 0.92 nm/sec |
| Cu | 1.83 nm/sec | 3.23 nm/sec |
| SiOₓ | less than 0.01 nm/sec | 0.21 nm/sec |
| SiNₓ | less than 0.01 nm/sec | 0.21 nm/sec |

When GHP-3 is used as the etching solution, the etching rate of MoW is 0.14 nm/sec, whereas the etching rate of Poly-OS is less than 0.01 nm/sec. This means that the oxide semiconductor layer 26 is hardly etched in forming the source electrode 32S and the drain electrode 32D by wet etching using GHP-3 when MoW is used for the conductive film of the source electrode 32S and drain electrode 32D of the semiconductor device 10 (more specifically, the first metal film in contact with the oxide semiconductor layer 26). Specifically, when the source electrode 32S and the drain electrode 32D have a single layer structure of MoW alloy or a Cu/MoW structure, the oxide semiconductor layer 26 is hardly etched by GHP-3.

Further, when BTF-3 is used as the etching solution, the etching rate of Ti and Al is 0.93 nm/sec and 0.92 nm/sec, respectively, whereas the etching rate of Poly-OS is less than 0.01 nm/sec. This means that the oxide semiconductor 26 is hardly etched in forming the source electrode 32S and the drain electrode 32D by wet etching using BTF-3 when Ti is used for the source electrode 32S and the drain electrode 32D of the semiconductor device 10 (more specifically, the first metal film in contact with the oxide semiconductor layer 26). Specifically, when the source electrode 32S and the drain electrode 32D 20) have a single layer structure of Ti, a Cu/Ti structure, or a Ti/Al/Ti structure, the oxide semiconductor layer 26 is hardly etched by BTF-3.

In addition, when BTF-3 is used as the etching solution, SiOₓ and SiNₓ are etched. This is because BTF-3 contains hydrofluoric acid. On the other hand, since Poly-OS has a high etching resistance even to hydrofluoric acid, Poly-OS is hardly etched by BTF-3 containing hydrofluoric acid. Therefore, when the source electrode 32S and the drain electrode 32D are formed by wet etching using BTF-3, the gate insulating layer 16 may be etched more than the oxide semiconductor layer 26. In this case, in the gate insulating layer 16, the thickness of the region that does not overlap the oxide semiconductor layer 26 is smaller than the thickness of the region that overlaps the oxide semiconductor layer 26.

As shown in Table 1, Poly-OS is hardly etched by GHP-3 and BTF-3. Therefore, a resist pattern was formed on each material, and wet etching (room temperature) of each material was performed using the resist pattern as a mask. After wet etching, the thickness of each material was measured. The etching rate of each material was calculated based on the etching time and the thickness. Table 2 shows the calculated etching rate of each material. In addition, “less than 0.01 nm/min” in Table 2 means that almost no etching is performed by wet etching with an etching time of 5 min.

TABLE 2

| | GHP-3 | BTF-3 |
|---|---|---|
| Poly-OS | 0.15 nm/min | less than 0.01 nm/min |
| MoW | 8.45 m/min | 5.22 nm/min |
| Ti | 0.11 nm/min | 56.07 nm/min |
| Al | 0.80 nm/min | 55.05 nm/min |
| Cu | 0.15 nm/min | less than 0.01 nm/min |
| SiOₓ | less than 0.01 nm/min | 12.75 nm/min |
| SiNₓ | less than 0.01 nm/min | 12.87 nm/min |

By increasing the etching time, it was possible to calculate the etching rate of Poly-OS with respect to GHP-3 as shown in Table 2. As a result, even when over-etching is performed for 1 min in forming the source electrode 32S and the drain electrode 32D by wet etching using BTF-3, the difference between the thickness of the source region or the drain region and the thickness of the channel region is less than or equal to 1 nm in the oxide semiconductor layer 26. On the other hand, it was not possible to calculate the etching rate of Poly-OS with respect to BTF-3. This means that Poly-OS has a very high etching resistance with respect to BTF-3. Therefore, when over-etching is performed for 1 min in forming the source electrode 32S and drain electrode 32D by wet etching using BTF-3, the oxide semiconductor layer 26 including Poly-OS is hardly etched, and the gate insulating layer 16 including SiOₓ is etched by about 13 nm. In other words, the difference between the thickness of the source region or the drain region and the thickness of the channel region is less than or equal to 1 nm or less in the oxide semiconductor layer 26, and the difference between the thickness of the region that overlaps the oxide semiconductor 26 and the thickness of the region that does not overlap the oxide semiconductor 26 is greater than or equal to 10 nm in the gate insulating layer 16.

### [Electrical Characteristics]

The semiconductor device 10 was manufactured according to the flowchart shown in FIG. 3 of the First Embodiment, and then the electric characteristics of the semiconductor device 10 were measured. In manufacturing the semiconductor device 10, a single layer structure of Ti was used for the source electrode 32S and the drain electrode 32D. In addition, in manufacturing the semiconductor device 10, the step S1008 in the flowchart shown in FIG. 3 was not performed. Further, in order to investigate the influence of over-etching in forming the source electrode 32S and the drain electrode 32D, after just-etching was performed on the single layer structure of Ti using a mixed solution of ammonia water and hydrogen peroxide solution (NH₃/H₂O₂ solution), multiple samples with different over-etching conditions were prepared. Table 3 shows the conditions for each sample.

TABLE 3

| | Over-etching conditions |
|---|---|
| Sample A | none |
| Sample B-1 | 30 sec using GHP-3 |
| Sample B-2 | 60 sec using GHP-3 |
| Sample C-1 | 30 sec using BTF-3 |
| Sample C-2 | 60 sec using BTF-3 |

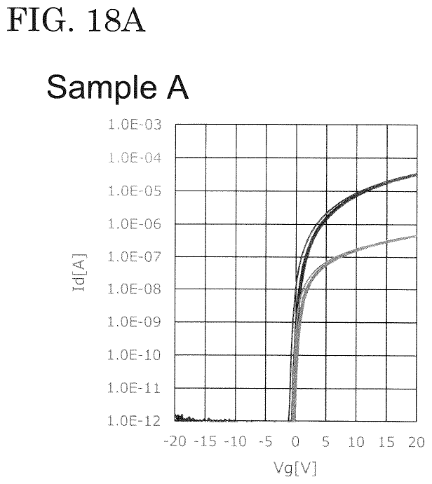

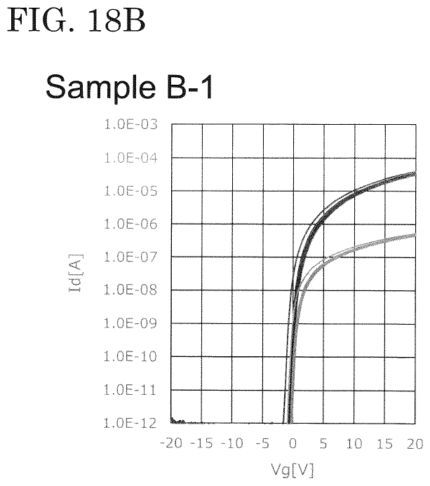

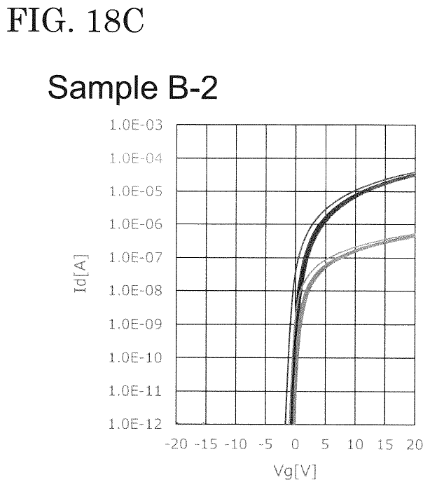

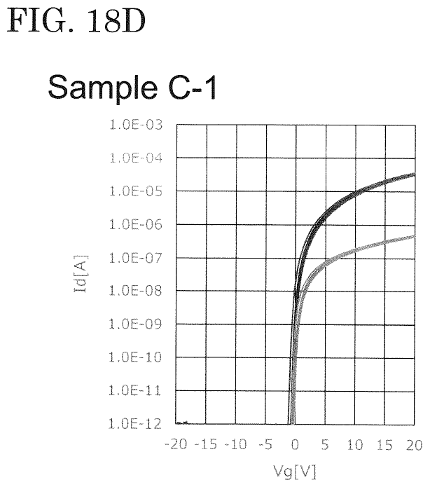

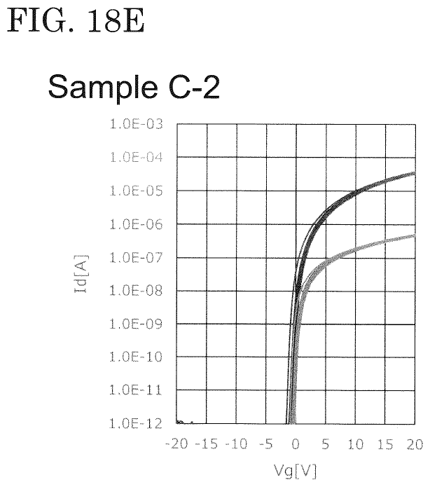

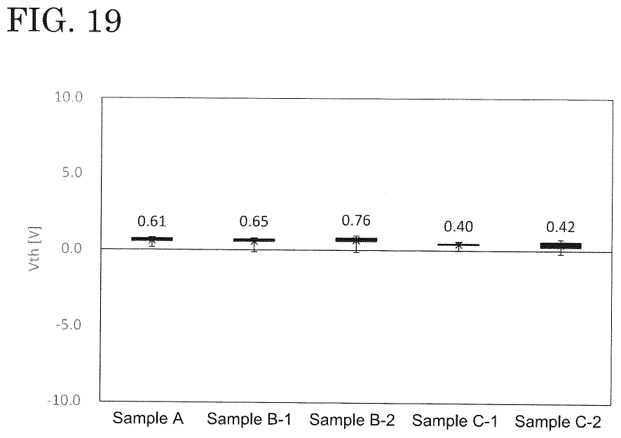

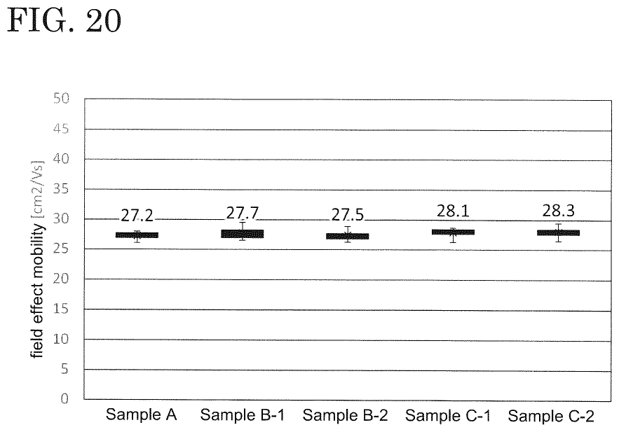

FIGS. 18A to 18E are graphs showing electrical characteristics of each sample in the example. The horizontal axis of each of the graphs in FIGS. 18A to 18E is the gate voltage (Vg), and the vertical axis is the drain current (Id). FIG. 19 is a graph showing the threshold value (Vth) calculated from the electrical characteristics of each sample in the Examples. FIG. 20 is a graph showing the field effect mobility (the field effect mobility in a linear region) calculated from the electrical characteristics of each sample in the Examples. Table 4 shows the conditions for measuring the electrical characteristics.

TABLE 4

| | |
|---|---|
| Channel Region Size | W/L = 6.0 μm/6.0 μm |
| Source-Drain | 0.1 V, 10 V |
| Voltage | |
| Gate Voltage | −20 V to +20 V (0.2 V Step) |
| Measurement | room temperature, dark room |
| Environment | |
| Number of | 9 points within the substrate |
| Measurement Points | |

FIGS. 18A to 18E shows the graphs of the electrical characteristics of each sample in which the measurement results of nine semiconductor devices 10 overlap each other. As understood from FIGS. 18A to 18E, the variation in the electrical characteristics of each sample is small. Further, as shown in FIGS. 19 and 20, variations in the threshold value and the field effect mobility are small in each sample. This is considered to be because the oxide semiconductor layer 26 is not etched in forming the source electrode 32S and the drain electrode 32D, so that the variation in the shape of the oxide semiconductor layer 26 is suppressed and the electrical characteristics are stabilized.

FIG. 19 also shows the average value of the threshold value for each sample. As understood from FIG. 19, the average values of the threshold values of the samples are all positive values, and indicate that the semiconductor device 10 is of the enhancement type. Further, FIG. 20 also shows the average value of the field effect mobility in each sample. As understood from FIG. 20, the average values of the field effect mobilities of the samples are all greater than 25 cm²/Vs, and indicate that the semiconductor device 10 has a field effect mobility greater than or equal to 20 cm²/Vs.

Although Sample B-1 and Sample B-2 differ in the time of over-etching in wet etching using GHP-3, no influence by the time of over-etching is confirmed. Further, although sample C-1 and sample C-2 differ in the time of over-etching in wet etching using BTF-3, no influence of the time of over-etching is confirmed. Furthermore, although Samples B-1 and B-2 and Samples C-1 and C-2 are different from each other in etching solutions in wet etching, no influence due to the difference in etching solution is confirmed. The oxide semiconductor layer 26 including Poly-OS has an excellent etching resistance, and the process margin can be widened in manufacturing the semiconductor device 10 using the oxide semiconductor layer 26. As a result, the yield in manufacturing the semiconductor device 10 is improved.

Each of the embodiments and modifications described above as the embodiments of the present invention can be appropriately combined and implemented as long as no contradiction is caused. Furthermore, the addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a gate electrode;
a gate insulating layer over the gate electrode;
an oxide semiconductor layer having a polycrystalline structure over the gate insulating layer;
a source electrode and a drain electrode over the oxide semiconductor layer; and
an interlayer insulating layer in contact with the oxide semiconductor layer, the interlayer insulating layer covering the source electrode and the drain electrode,
wherein the oxide semiconductor layer comprises a first region overlapping one of the source electrode and the drain electrode and a second region in contact with the interlayer insulating layer, and
a difference between a thickness of the first region and a thickness of the second region is less than or equal to 1 nm.

2. The semiconductor device according to claim 1,
wherein the source electrode and the drain electrode comprise a first metal layer,
an etching rate of the first metal layer with respect to an etching solution used in forming the first metal layer is greater than or equal to 0.1 nm/sec, and
an etching rate of the oxide semiconductor layer with respect to the etching solution is less than 0.01 nm/sec.

3. The semiconductor device according to claim 2,
wherein the source electrode and the drain electrode further comprise a second metal layer on the first metal layer, and
an etching rate of the second metal layer with respect to the etching solution is greater than or equal to 0.5 nm/sec.

4. The semiconductor device according to claim 3, wherein the first layer contains molybdenum.

5. The semiconductor device according to claim 3, wherein the etching solution comprises a chelating agent.

6. The semiconductor device according to claim 2, wherein the etching rate of the first metal layer is greater than or equal to 0.5 nm/sec.

7. The semiconductor device according to claim 6,
wherein the source electrode and the drain electrode further comprise a second metal layer containing copper on the first metal layer, and
wherein an etching rate of the second metal layer with the etching solution is greater than or equal to 1.0 nm/sec.

8. The semiconductor device according to claim 7, wherein the first layer contains titanium.

9. The semiconductor device according to claim 7, wherein the etching solution comprises phosphoric acid.

10. The semiconductor device according to claim 1,
wherein the oxide semiconductor layer contains indium and at least one or more metal elements other than the indium, and
a ratio of the indium to the indium and the at least one or more metal elements is greater than or equal to 50%.

11. A method for manufacturing a semiconductor device comprising the steps of:
forming a gate electrode;
forming a gate insulating layer over the gate electrode;
forming an oxide semiconductor layer having a polycrystalline structure over the gate insulating layer;
forming a source electrode and a drain electrode over the oxide semiconductor layer; and
forming an interlayer insulating layer in contact with the oxide semiconductor layer, the interlayer insulating layer covering the source electrode and the drain electrode;
wherein the oxide semiconductor layer comprises a first region overlapping one of the source electrode and the drain electrode and a second region in contact with the interlayer insulating layer, and
a difference between a thickness of the first region and a thickness of the second region is less than or equal to 1 nm.

12. The method for manufacturing a semiconductor device according to claim 11,
wherein the formation of the source electrode and the drain electrode comprises the steps of:
depositing a first metal film,
depositing a second metal film on the first metal film, and
etching the first metal film and the second metal film using an etching solution to form a first metal layer and a second metal layer on the first metal layer,
an etching rate of the first metal film with respect to the etching solution is greater than or equal to 0.1 nm/sec, and
an etching rate of the oxide semiconductor layer with respect to the etching solution is less than 0.01 nm/sec.

13. The method for manufacturing a semiconductor device according to claim 12,
wherein the second metal film contains copper, and
an etching rate of the second metal film with respect to the etching solution is greater than or equal to 0.5 nm/sec.

14. The method for manufacturing a semiconductor device according to claim 13, wherein the first layer contains molybdenum.

15. The method for manufacturing a semiconductor device according to claim 13, wherein the etching solution comprises a chelating agent.

16. The method for manufacturing a semiconductor device according to claim 12, wherein the etching rate of the first metal film is greater than or equal to 0.5 nm/sec.

17. The method for manufacturing a semiconductor device according to claim 16,
wherein the second metal film contains copper, and
an etching rate of the second metal film with respect to the etching solution is greater than or equal to 1.0 nm/sec.

18. The method for manufacturing a semiconductor device according to claim 17, wherein the first layer contains titanium.

19. The method for manufacturing a semiconductor device according to claim 17, wherein the etching solution comprises phosphoric acid.

20. The method for manufacturing a semiconductor device according to claim 1,
wherein the oxide semiconductor layer contains indium and at least one or more metal elements other than the indium, and
a ratio of the indium to the indium and the at least one or more metal elements is greater than or equal to 50%.
